(19) United States
(12) Patent Application Publication
(10) Pub. No.: US 2023/0021534 A1
(43) Pub. Date: Jan. 26, 2023

(54) ELECTRONIC DIE MANUFACTURING METHOD

(71) Applicant: STMICROELECTRONICS (TOURS) SAS, Tours (FR)

(72) Inventors: Olivier ORY, Tours (FR); Philippe RABIER, Joué-lés-Tours (FR)

(73) Assignee: STMICROELECTRONICS (TOURS) SAS, Tours (FR)

(21) Appl. No.: 17/858,797

(22) Filed: Jul. 6, 2022

(30) Foreign Application Priority Data
Jul. 16, 2021 (FR) 2107694

(51) Int. Cl. H01L 21/84; H01L 21/768; H01L 21/762; H01L 23/528; H01L 21/304; H01L 21/66

(52) U.S. Cl. CPC H01L 21/84; H01L 21/76898; H01L 21/76224; H01L 23/528; H01L 21/3043; H01L 22/12

(57) ABSTRACT

The present description concerns an electronic die manufacturing method comprising: a) the deposition of an electrically-insulating resin layer on the side of a first surface of a semiconductor substrate, inside and on top of which have been previously formed a plurality of integrated circuits, the semiconductor substrate supporting on a second surface, opposite to the first surface, contacting pads; and b) the forming, on the side of the second surface of the semiconductor substrate, of first trenches, electrically separating the integrated circuits from one another, the first trenches vertically extending in the semiconductor substrate and emerging into or on top of the resin layer.

### CROSS-REFERENCE TO RELATED APPLICATION(S)

This application claims the priority benefit of French patent application number FR2107694, filed on Jul. 16, 2021, entitled “ELECTRONIC DIE MANUFACTURING METHOD,” which is hereby incorporated by reference to the maximum extent allowable by law.

### BACKGROUND

### Technical Background

The present disclosure generally concerns the manufacturing of semiconductor electronic dies.

### Description of the Related Art

Conventionally, a method of manufacturing electronic dies may comprise a final electric test step, during which electric test signals are applied to die connection metallizations, by means of metal test pads electrically connected to an electronic testing device.

It would be desirable to at least partly improve certain aspects of known electronic die manufacturing methods.

### BRIEF SUMMARY

An embodiment provides an electronic die manufacturing method comprising:
a step a) of deposition of an electrically-insulating resin layer on the side of a first surface of a semiconductor substrate, inside and on top of which have been previously formed a plurality of integrated circuits, the semiconductor substrate supporting on a second surface, opposite to the first surface, contacting pads; and
a step b) of forming, on the side of the second surface of the semiconductor substrate, of first trenches, electrically separating the integrated circuits from one another, the first trenches vertically extending in the semiconductor substrate and emerging into or on top of the resin layer.

According to an embodiment, step b) is followed by a step c) of individualization of the electronic dies.

According to an embodiment, the individualization of step c) is achieved by the forming of second trenches in the first trenches.

According to an embodiment, the individualization of step c) is achieved by the thinning of the insulating resin layer.

According to an embodiment, the method comprises, between steps b) and c), a step d) of electric testing of the integrated circuits.

According to an embodiment, the first trenches extend across the entire thickness of the substrate.

According to an embodiment, the method comprises, between step a) and step b), a step of forming of third trenches extending, between the integrated circuits, from the first surface of the semiconductor substrate across a portion of the thickness of the semiconductor substrate.

According to an embodiment, the third trenches extend in the semiconductor substrate down to a depth in the range from 30% to 75% of the thickness of the semiconductor substrate.

According to an embodiment, the third trenches have a width greater than the width of the first trenches.

According to an embodiment, during step a), the thickness of the semiconductor substrate is in the range from 50 μm to 500 μm, preferably from 50 μm to 130 μm.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 illustrates, in a cross-section view, a step of an example of an electronic die manufacturing method according to a first embodiment;

FIG. 2 illustrates, in a cross-section view, another step of an example of an electronic die manufacturing method according to a first embodiment;

FIG. 3 illustrates, in a cross-section view, another step of an example of an electronic die manufacturing method according to a first embodiment;

FIG. 4 illustrates, in a cross-section view, another step of an example of an electronic die manufacturing method according to a first embodiment;

FIG. 5 illustrates, in a cross-section view, another step of an example of an electronic die manufacturing method according to a first embodiment;

FIG. 6 illustrates, in a cross-section view, another step of an example of an electronic die manufacturing method according to a first embodiment;

FIG. 7 illustrates, in a cross-section view, a step of an example of an electronic die manufacturing method according to a second embodiment;

FIG. 8 illustrates, in a cross-section view, another step of an example of an electronic die manufacturing method according to a second embodiment;

FIG. 9 illustrates, in a cross-section view, another step of an example of an electronic die manufacturing method according to a second embodiment;

FIG. 10 illustrates, in a cross-section view, another step of an example of an electronic die manufacturing method according to a second embodiment;

FIG. 11 illustrates, in a cross-section view, another step of an example of an electronic die manufacturing method according to a second embodiment; and

FIG. 12 illustrates, in a cross-section view, another step of an example of an electronic die manufacturing method according to a second embodiment.

### DETAILED DESCRIPTION

Like features have been designated by like references in the various figures. For example, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. For example, the forming of the integrated circuits present in the described electronic dies has not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the cross-section views of the corresponding drawings.

Unless specified otherwise, the expressions “around,” “approximately,” “substantially” and “in the order of” signify within 10%, and preferably within 5%.

A method of manufacturing electronic dies may include the simultaneous forming of a plurality of electronic dies, for example, identical or similar, inside and on top of a same semiconductor substrate. At the end of the method, a dicing step is implemented to individualize the dies.

Before the dicing step, an adhesive support film is attached on the side of one of the surfaces of the substrate, so that, at the end of the dicing step, once individualized, the dies remains supported by the support film.

A final electric test step may be implemented before the individual die dicing step. This enables to simultaneously test a plurality of dies while guaranteeing the mechanical stability of the dies during the application of the test probes. However, parasitic electric couplings, via the substrate, may then exist between the different dies, which may alter the results of the tests.

As a variant, the test step may be implemented after the individual die dicing step. This enables to ensure the electrical isolation of the dies from one another during the test. However, the mechanical stability of the dies is then no longer ensured. This may pose a problem, particularly for dies of small dimensions, having a mechanical stability which is then too low to allow the application of the test probes.

It should be noted that electronic die manufacturing methods where at least a portion of the sides of the die substrate is left free, not coated with a protection resin, at the end of the dicing step, are here more particularly considered. Indeed, there exist manufacturing methods where, at the end of the dicing step, the sides of the die substrate are entirely covered with protection resin. Such methods are however more expensive.

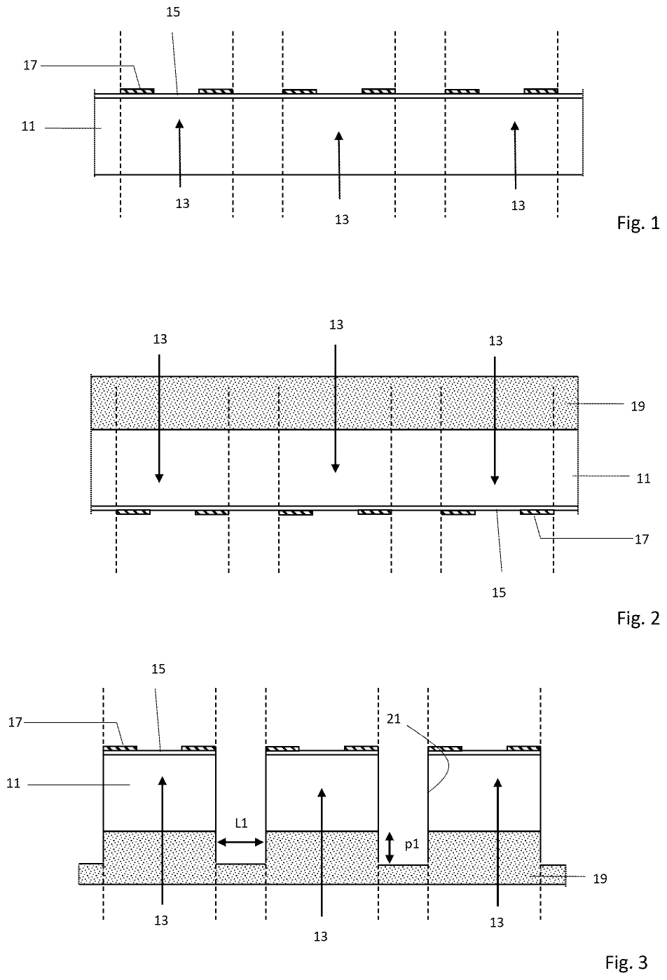

FIGS. 1 to 6 are cross-section views illustrating successive steps of an example of an electronic die manufacturing method according to an embodiment.

FIG. 1 corresponds to a structure comprising a semiconductor substrate 11 inside and on top of which integrated circuits 13 have been previously formed. Circuits 13 are for example all identical, to within manufacturing dispersions.

Substrate 11 may correspond to a wafer of a semiconductor material, for example, silicon having had its thickness decreased to obtain a thickness corresponding to the desired final thickness of substrate 11 in the electronic die. Substrate 11 has, for example, a thickness in the range from 50 μm to 500 μm, for example in the range from 50 μm to 130 μm.

The structure of FIG. 1 further comprises a stack of insulating and conductive layers also called interconnection stack 15 coating the upper surface of substrate 11. Interconnection stack 15 further comprises, on its upper surface side, for each integrated circuit 13, one or a plurality of contacting pads 17. Contacting pads 17 may comprise a stack of one or a plurality of metal layers. Contacting pads 17 are for example under bump metallizations (UBM).

Each integrated circuit 13 for example comprises one or a plurality of electronic components (transistors, diodes, thyristors, triacs, etc.).

In FIG. 1, three integrated circuits 13 have been shown, it being understood that the number of integrated circuits 13 formed inside and on top of substrate 11 may be different from three. In practice, substrate 11 is a wafer of a semiconductor material, for example, silicon, and several tens or even several hundreds or thousands of integrated circuits 13 are formed inside and on top of substrate 11. Integrated circuits 13 are then, for example, organized in an array of rows and columns following a regular grid.

In the rest of this description, in the orientation of FIG. 1, the lower surface of the structure or of the substrate 11, e.g., the surface without the contacting pads 17, is referred to as being the back side and the upper surface of the structure or of the substrate 11, e.g., the surface with the contacting pad 17, is referred to as being the front side, for descriptive and illustrative purposes only.

FIG. 2 illustrates, in a cross-section view, a step of deposition of an electrically-insulating resin protection layer 19 on the back side of the structure illustrated in FIG. 1 (e.g., the lower surface in the orientation of FIG. 1).

It should be noted that in the example of FIG. 2, the orientation of the structure is inverted with respect to the cross-section view of FIG. 1.

During this step, the back side of the structure is integrally covered (full plate) with resin 19. Resin 19 is for example, an epoxy resin, parylene, or another electrically-insulating polymer or other electrically-insulating materials. In this example, resin 19 is deposited on top of and in contact with the back side of semiconductor substrate 11. The resin for example has a substantially uniform thickness all over the back side of substrate 11. As an example, resin 19 is initially deposited in liquid or viscous form, and then hardened, for example, by anneal.

Resin 19, in some implementations, has a relatively large thickness to rigidify the structure, so that it can undergo subsequent steps, particularly of dicing, with a limited risk of breakage. As an example, resin layer 19 has a thickness greater than 70 μm.

FIG. 3 illustrates, in a cross-section view, a step of forming of dicing trenches 21 from the front side of the structure illustrated in FIG. 2 (shown as the lower surface in the orientation of FIG. 2).

It should be noted that in the example of FIG. 3, the orientation of the structure is inverted with respect to the cross-section view of FIG. 2.

Trenches 21 extend between circuits 13 so that each circuit 13 is laterally separated from its neighbors by trenches 21. As an example, each circuit 13 is entirely delimited or surrounded, laterally, by trenches 21. Trenches 21 may for example, in top view, form a continuous gate extending between integrated circuits 13.

In the shown example, trenches 21 extend vertically, from the front side of the structure (that is, the upper surface in the orientation of FIG. 3), more particularly from the upper surface of stack 15. Trenches 21 cross the entire thickness of stack 15 and substrate 11, and a portion of the thickness of resin 19. Trenches 21 stop in resin layer 19 without entirely crossing it.

Thus, at the end of the step of forming of trenches 21, each integrated circuit 13 is electrically insulated from but mechanically fastened or coupled to the neighboring integrated circuits 13.

Trenches 21 are for example formed by plasma cutting, by sawing by means of a blade, or by laser cutting.

Trenches 21 have a width L1, for example in the range from 20 μm to 150 μm, for example in the order of 50 μm. Trenches 21 extend in resin 19 down to a depth p1, for example, greater than 20 μm. In some implementations, the thickness of resin 19 remaining at the bottom of trenches 21 is at least 50 μm.

In some embodiments, not shown for simplicity, trenches 21 may stop on the upper surface of resin layer 19, e.g., the surface of resin layer 19 that interfaces with the substrate 11. In this case, depth pl is substantially zero. This may for example occur with a plasma cutting, selective over resin 19.

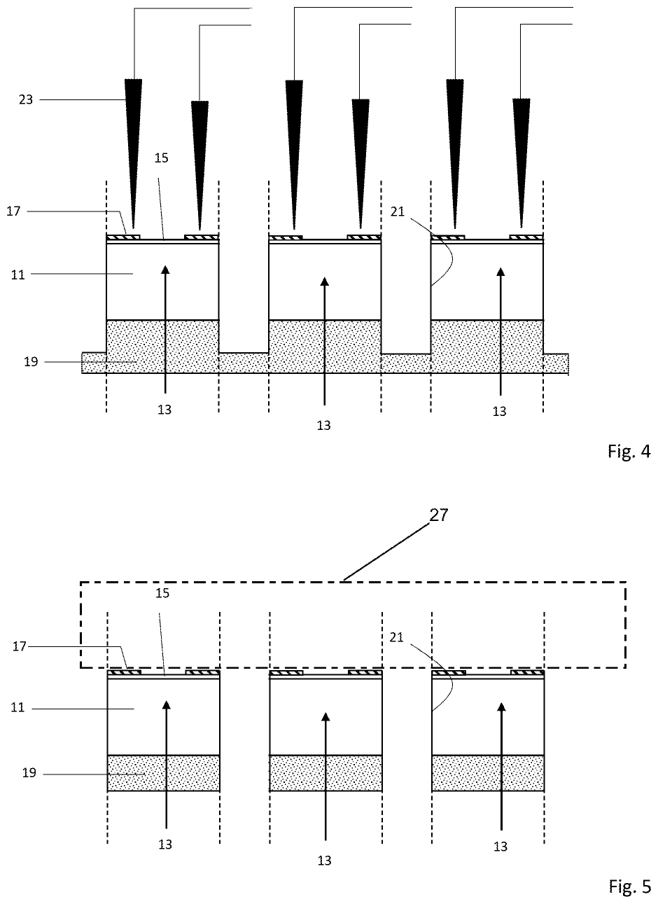

FIG. 4 illustrates, in a cross-section view, a step of electric testing of integrated circuits 13.

The electric test comprises in this example applying electric test signals to the connection metallizations 17 of the dies, by means of metal test probes 23 electrically connected to a testing device (not shown). As an example, at this step, a plurality of dies are electrically tested in parallel.

During this step, the integrated circuits 13 formed on a same semiconductor substrate wafer 11 are for example all tested. As an example, integrated circuits 13 are simultaneously tested in groups of a plurality of circuits 13. For example, circuits 13 are distributed into a plurality of groups of a plurality of circuits 13 each, the circuits 13 of a same group being simultaneously tested and the circuits 13 of distinct groups being sequentially tested. As an example, integrated circuits 13 are simultaneously tested in groups of eight by eight, sixteen by sixteen, sixty-four by sixty-four, or even in groups of larger dimensions.

FIGS. 5 and 6 illustrate two examples of implementation of a step of dicing of the structure illustrated in FIG. 4 into individual dies, each comprising a single integrated circuit 13.

In the example of FIG. 5, the die individualization is obtained by thinning resin layer 19 from the back side.

Prior to this step, an adhesive support film 27, for example, a flexible film, as shown in FIG. 5, is attached on the front side of the structure.

A portion of the thickness of resin 19 is then removed from its back side. The thinning is for example carried out by mechanical polishing or chemical mechanical polishing (CMP).

In the shown example, the thinning is interrupted when the bottom of trenches 21 is reached and when the desired final thickness of resin layer 19 is reached. As an example, the thickness of resin 19 remaining on the back side of the dies at the end of the thinning step is smaller than 100 μm, for example, smaller than 30 μm.

At the end of the step illustrated in FIG. 5, the structure corresponds to a plurality of individual electronic dies, only coupled by the support film (not shown in FIG. 5). Each of the individual dies comprises a single integrated circuit 13. The dies can then be collected, by their back side, from the support film, for their assembly in an external device.

As a variant, the structure illustrated in FIG. 5 is placed by its back side on another support film, for example, a flexible film, and then the support film located on the front side of the structure is removed. The dies can then be collected, by their front side, from this other support film, for their assembly in an external device.

In the example of FIG. 6, the individualization of the dies is obtained by the forming of through trenches 25 from the front side of the structure.

Prior to this step, the structure is placed, by its back side (lower surface in the orientation of FIG. 6), on a support film 29, for example, a flexible film, as shown in FIG. 6.

To cut the structure into individual dies, each comprising a single integrated circuit 13, trenches 25 are formed in front of trenches 21 in resin 19. More particularly, there is formed in each trench 21 a trench 25 parallel to said trench 21. In this example, trenches 25 extend all along the length of trenches 21. Trenches 25 extend vertically through resin 19, from the bottom of trenches 21, and emerge on the back side of resin layer 19. Thus, resin 19 is cut in front of trenches 21. Trenches 25 have a width L2 smaller than or equal to width L1.

Trenches 25 may for example be formed by sawing, by using a cutting blade having a width smaller than that used for the forming of trenches 21. Trenches 25 may as a variant be formed by laser ablation or by any other dicing technique. Trenches 21 and trenches 25 are for example aligned along a same central axis.

At the end of the step illustrated in FIG. 6, the structure corresponds to a plurality of individual electronic dies, only coupled by the support film 29, each of the individual dies comprising a single integrated circuit 13. The dies may be collected from this support film 29, for the assembly in an external device.

At the end of the method described in relation with FIGS. 1 to 6, elementary dies where only the back side of substrate 11 is coated with a protection resin layer 19 are obtained. For example, the sides of substrate 11 remain free, that is, not coated with electrically-insulating protection resin.

An advantage of the above-described method is that it enables to obtain an intermediate structure where integrated circuits 13 are electrically insulated from but mechanically fastened to the neighboring integrated circuits 13 (FIG. 3). The final electric testing of the chips may advantageously be performed on this intermediate structure, before the chip individualization step.

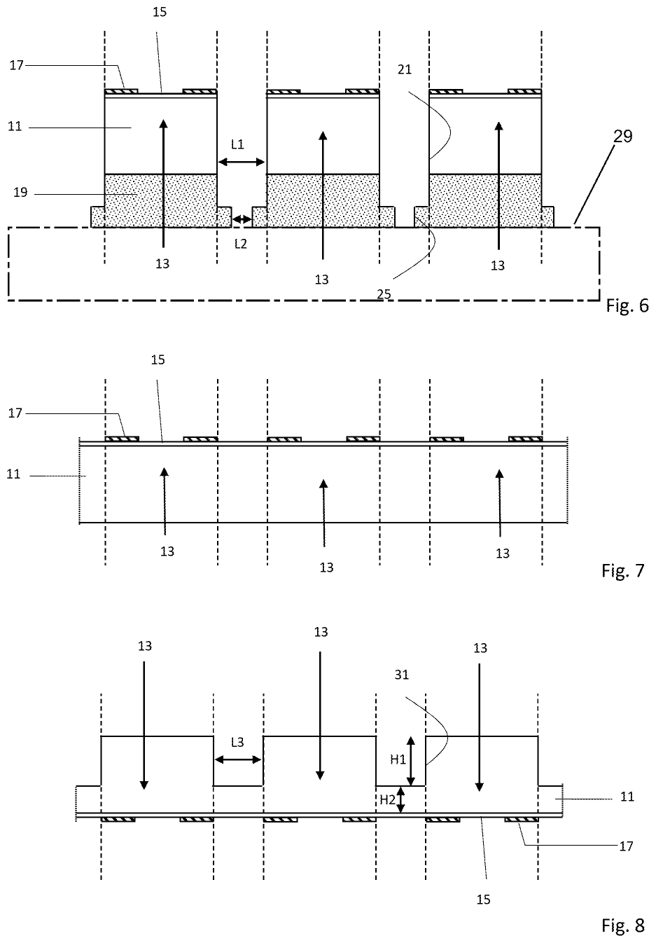

FIGS. 7 to 12 are cross-section views illustrating successive steps of an example of an electronic die manufacturing method according to an embodiment.

FIG. 7 corresponds to a structure identical or similar to the structure illustrated in FIG. 1 and will not be detailed again hereafter.

FIG. 8 illustrates, in a cross-section view, a step of forming of dicing trenches 31 from the back side of the structure illustrated in FIG. 7.

It should be noted that in the example of FIG. 8, the orientation of the structure is inverted with respect to the cross-section view of FIG. 7.

In the shown example, trenches 31 extend vertically from the back side of substrate 11 and continue into substrate 11. In this example, trenches 31 are non-through, that is, they do not emerge on the front side of substrate 11.

In the shown example, trenches 31 extend between circuits 13 so that, in top view, each circuit 13 is separated from the neighboring circuits 13 by trenches 31. Trenches 31 may for example, in top view, form a continuous grid extending between integrated circuits 13.

Trenches 31 vertically extend down to a depth H1. Depth H1 may be in the range from 30% to 75% of the thickness of substrate 11. As an example, depth H1 is selected so that there remains a thickness H2 of substrate 11 in the range from 20 μm to 50 μm between the bottom of trenches 31 and the front side of substrate 11. Trenches 31 for example have a width L3 in the range from 20 μm to 120 μm, in some implementations in the range from 40 μm to 70 μm, for example, equal to approximately 50 μm.

In some implementations, trenches 31 are for example formed by plasma cutting. In some implementations, trenches 31 are formed by sawing by means of a blade.

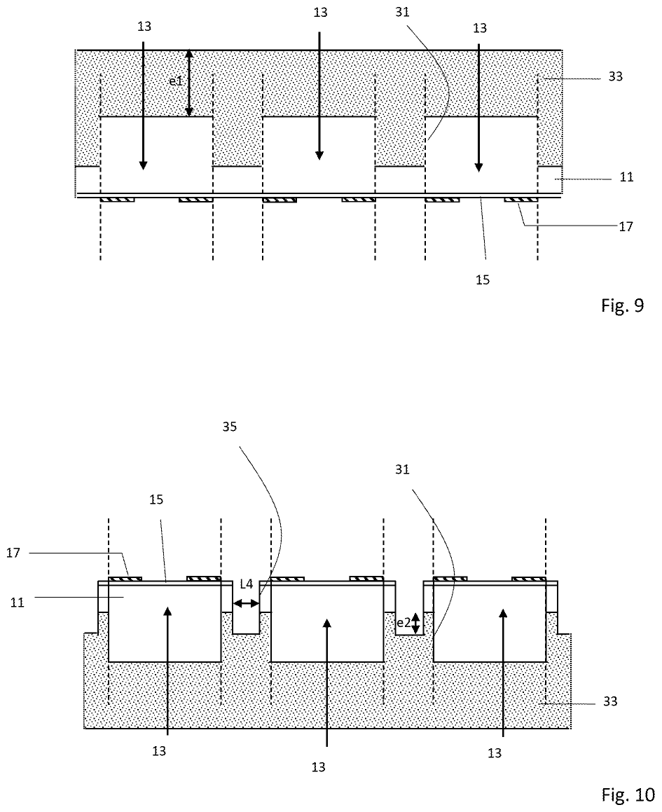

FIG. 9 illustrates, in a cross-section view, a step of deposition of a protection layer 33 on the back side of the structure illustrated in FIG. 8.

During this step, the back side of the structure (that is, the upper surface in the orientation of FIGS. 8 and 9) is integrally covered (full plate) with resin 33. For example, trenches 31 are filled and the back side of substrate 11 is covered. Resin 33 is for example identical or similar to the resin 19 described in relation with FIGS. 1 to 6.

As an example, resin 33 is deposited so that it forms a layer having a non-zero thickness e1, for example, a thickness e1 in the order of 20 μm, on the back side of substrate 11, outside of trenches 31.

FIG. 10 illustrates, in a cross-section view, a step of forming of dicing trenches 35 from the front side of the structure illustrated in FIG. 9.

It should be noted that in the example of FIG. 10, the orientation of the structure is inverted with respect to the cross-section view of FIGS. 8 and 9.

During this step, trenches 35 are formed in substrate 11 and in the resin 33 located inside of trenches 31. Trenches 35 are formed in all the trenches 31 and all along their length. Trenches 35 extend vertically through substrate 11 and a portion of the thickness of resin 33. As an example, trenches 35 extend in resin 33 down to a depth e2 in the range from 10 μm to 40 μm.

Trenches 35 have a width L4. Width L4 is smaller than width L3 so that a portion of each of the lateral sides of substrate 11 of each die, delimited by trenches 35, remains covered with resin 33, for example, across a thickness in the range from 5 μm to 10 μm. Trenches 35 may for example be formed by sawing, by using a cutting blade having a width smaller than that used to form trenches 31. Trenches 35 may as a variant be formed by laser ablation or by any other dicing technique, for example, by plasma etching. Trenches 31 and trenches 35 are for example aligned along a same central axis. Width L4 is for example in the range from 5 μm to 20 μm.

As a variant, not shown, trenches 35 stop on the upper surface of resin 33 (zero thickness e2). This may for example occur when trenches 35 are formed by means of a plasma cutting, selective over resin 33.

At the end of the step of forming of trenches 35 illustrated in FIG. 10, each integrated circuit 13 is electrically insulated from but mechanically fastened to the neighboring integrated circuits 13.

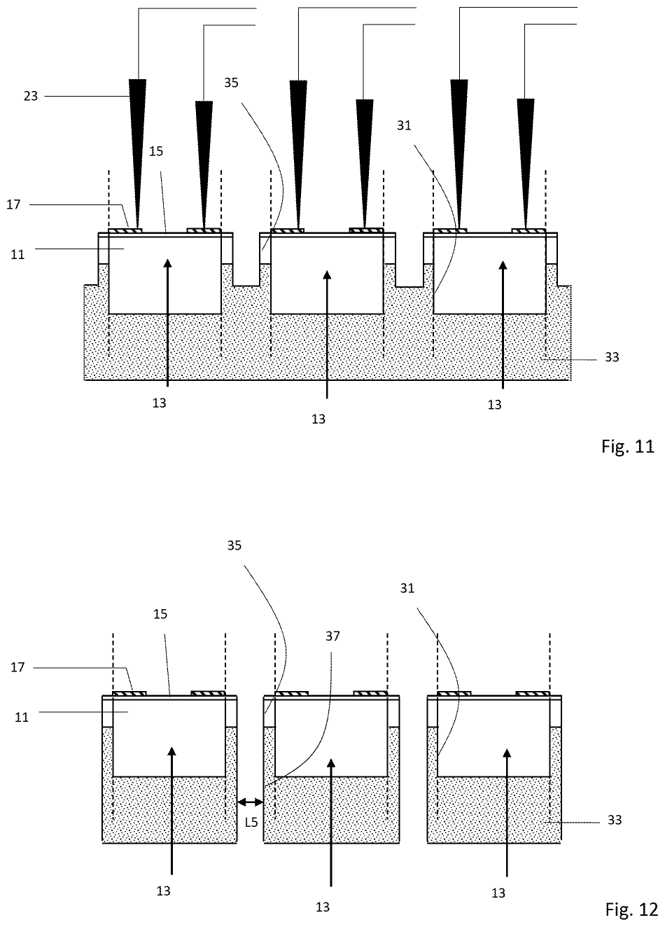

FIG. 11 illustrates, in a cross-section view, a step of electric testing of integrated circuits 13, identical or similar to the test step illustrated in FIG. 4.

FIG. 12 illustrates, in a cross-section view, a step of dicing of the structure illustrated in FIG. 11 into individual dies, each comprising a single integrated circuit 13.

During this step, through trenches 37 are formed from the front side of the structure illustrated in FIG. 10 or 11 (that is, the upper surface in the orientation of FIGS. 10 and 11).

Prior to this step, the structure is placed, by its back side (lower surface in the orientation of FIG. 12), on a support film, for example, a flexible film, not shown in FIG. 12.

To cut the structure into individual dies, trenches 37 are formed in front of trenches 35 in resin 33. More particularly, one forms in front of each trench 35 a trench 37 parallel to each trench 35. In this example, trenches 37 extend all along the length of trenches 35. Trenches 37 vertically extend so that the resin 33 present in trenches 31 is cut in front of trenches 35. Trenches 37 have a width L5 smaller than or equal to the width L3 of trenches 31. In some implementations, the width of trenches L5 is greater than or equal to the width L4 of trenches 31 to avoid the forming of a step in the resin.

Trenches 37 may for example be formed by sawing, by using a cutting blade having a width smaller than or equal to (equal in the shown example) that used to form trenches 31. Trenches 37 may as a variant be formed by laser ablation. Trenches 31, trenches 35, and trenches 37 are for example aligned along a same central axis.

At the end of the step illustrated in FIG. 12, the structure corresponds to a plurality of individual electronic dies, only coupled by the support film (not shown in FIG. 12), each of the individual dies comprising a single integrated circuit 13. The dies may be collected from this support film, for their assembly in an external device.

At the end of the method described in relation with FIGS. 7 to 12, elementary dies are obtained where only the back side and a lower portion of the sides of substrate 11 are coated with a protection resin 33. For example, an upper portion of the sides of substrate 11 remains free, that is, not coated with an electrically-insulating protection resin.

Here again, an advantage of the described method is that it enables to obtain an intermediate structure where integrated circuits 13 are electrically insulated from the neighboring integrated circuits 13 and are mechanical fastened to the neighboring integrated circuits 13 (FIG. 10). The final electric testing of the dies may advantageously be performed on this intermediate structure, before the die individualization step.

An advantage of the described embodiments and implementation modes is that they are compatible with usual electronic die manufacturing methods.

Another advantage of the described embodiments and implementation modes is that they enable to electrically test each of the dies during their manufacturing process.

Another advantage of the described embodiments and implementation modes is that they allow a good holding of the dies when they are being electrically tested.

Another advantage of the described embodiments and implementation modes is that they are compatible with usual testing devices.

Various embodiments and variants have been described. Those skilled in the art will understand that certain features of these various embodiments and variants may be combined, and other variants will occur to those skilled in the art. For example, the described embodiments are for example not limited to the examples of dimensions and of materials mentioned hereabove.

It should be noted that the described embodiments are particularly adapted to dies of small dimensions, for example, having, in top view, a surface area smaller than 1 mm², in some implementations smaller than 0.3 mm². The described embodiments are for example adapted to dies where contacting pads 17 are aligned on a single row, in some implementations to dies of cuboid shape only having two contact pads 17 on a same connection surface. However, the described embodiments are however not limited to these specific cases.

Finally, the practical implementation of the described embodiments and variations is within the abilities of those skilled in the art based on the functional indications given hereinabove.

Electronic die manufacturing method may be summarized as including a) the deposition of an electrically-insulating resin layer (19; 33) on the side of a first surface of a semiconductor substrate (11), inside and on top of which have been previously formed a plurality of integrated circuits (13), the semiconductor substrate supporting on a second surface, opposite to the first surface, contacting pads (17); and b) the forming, on the side of the second surface of semiconductor substrate (11), of first trenches (21; 35), electrically separating the integrated circuits (13) from one another, the first trenches vertically extending in the semiconductor substrate and emerging into or on top of the resin layer (19; 33).

Step b) may be followed by a step c) of individualization of the electronic dies.

The individualization of step c) may be performed by the forming of second trenches (25; 37) in the first trenches (21; 35).

The individualization of step c) may be performed by the thinning of insulating resin layer (19).

The method may include, between steps b) and c), a step d) of electric testing of the integrated circuits (13).

The first trenches (21) may extend across the entire thickness of the substrate (11).

The method may include between step a) and step b), a step of forming of third trenches (31) extending between the integrated circuits (13), from the first surface of the semiconductor substrate (11), across a portion of the thickness of the semiconductor substrate.

The third trenches (31) may extend in the semiconductor substrate (11) down to a depth (H1) in the range from 30% to 75% of the thickness of the semiconductor substrate.

The third trenches (31) may have a width (L3) greater than the width (L5) of the first trenches (37).

During step a), the thickness of the semiconductor substrate (11) may be in the range from 50 μm to 500 μm, in some implementations from 50 μm to 130 μm.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic die manufacturing method, comprising:
depositing an electrically-insulating layer on a first surface of a semiconductor substrate, the semiconductor substrate including a plurality of integrated circuits and contact pads coupled to the plurality of integrated circuits, the contact pads on a second surface of the semiconductor substrate that is opposite to the first surface; and
forming first trenches on the second surface of the semiconductor substrate, the first trenches electrically separating the plurality of integrated circuits from one another, the first trenches extending from the second surface into the semiconductor substrate, and the first trenches reaching the electrically-insulating layer or extending into the electrically-insulating layer.

2. The method according to claim 1, comprising severing the semiconductor substrate into individual semiconductor dies after the forming the first trenches.

3. The method according to claim 2, wherein the severing the semiconductor substrate includes forming second trenches in the first trenches.

4. The method according to claim 2, wherein the severing the semiconductor substrate includes thinning the electrically-insulating layer.

5. The method according to claim 2, comprising electric testing the plurality of integrated circuits before the severing the semiconductor substrate and after the forming the first trenches.

6. The method according to claim 1, wherein the first trenches each extends across an entire thickness of the semiconductor substrate between the first surface and the second surface.

7. The method according to claim 1, comprising, after the depositing the electrically-insulting layer and before the forming the first trenches, forming third trenches among the plurality of integrated circuits, the third trenches extending from the first surface of the semiconductor substrate into a portion of a thickness of the semiconductor substrate between the first surface and the second surface.

8. The method according to claim 7, wherein the third trenches each extends in the semiconductor substrate down to a depth in a range from 30% to 75% of the thickness of the semiconductor substrate between the first surface and the second surface.

9. The method according to claim 7, wherein the third trenches each has a width that is greater than a width of each of the first trenches.

10. The method according to claim 1, wherein a thickness of the semiconductor substrate is in a range from 50 μm to 500 μm.

11. The method of claim 10, wherein the thickness of the semiconductor substrate is in a range from 50 μm to 130 μm.

12. An method, comprising:
forming a plurality of first trenches on a first surface of a semiconductor substrate, the semiconductor substrate including a plurality of integrated circuits and contact pads coupled to the plurality of integrated circuits, the contact pads on a second surface of the semiconductor substrate that is opposite to the first surface, the plurality of first trenches each terminating within the semiconductor substrate before reaching the second surface;
depositing an electrically-insulating layer on the first surface of the semiconductor substrate and filling the plurality of first trenches; and
forming, on the second surface of the semiconductor substrate, a plurality of second trenches, each second trench of the plurality of second trenches overlapping a first trench of the plurality of first trenches and extending from the second surface at least to the electrically-insulating layer in the first trench, the plurality of second trenches and the electrically-insulating layer separating the plurality of integrated circuits from one another.

13. The method according to claim 12, wherein the plurality of second trenches each extends into the electrically-insulting layer.

14. The method according to claim 12, comprising severing the semiconductor substrate through second trenches of the plurality of second trenches.

15. The method according to claim 14, comprising electric testing the plurality of integrated circuits before the severing the semiconductor substrate and after the forming the plurality of second trenches.

16. The method according to claim 12, wherein the first trenches each extends in the semiconductor substrate down to a depth in a range from 30% to 75% of the thickness of the semiconductor substrate between the first surface and the second surface.

17. The method according to claim 12, wherein the plurality of first trenches each has a width that is greater than a width of each of the plurality of second trenches.

18. A structure, comprising:
an electrically insulating layer;
a plurality of semiconductor dies on the electrically insulating layer in a first direction, each semiconductor die of the plurality of semiconductor dies including electrical contact structures on an surface of the semiconductor die distal from the electrically insulating layer; and
a plurality of trenches that separate the plurality of semiconductor dies from one another in a second direction that transverses the first direction.

19. The structure of claim 18, wherein the electrically insulating layer is between two semiconductor dies of the plurality of semiconductor dies in the second direction.

20. The structure of claim 18, wherein the plurality of trenches each extends into the electrically insulating layer.
